(19) United States
(12) Patent Application Publication
(10) Pub. No.: US 2025/0107143 A1
(43) Pub. Date: Mar. 27, 2025

(54) SEMICONDUCTOR DEVICE HAVING A VERTICAL POWER TRANSISTOR WITH A METAL SILICIDE GATE REGION

(71) Applicant: Infineon Technologies Austria AG, Villach (AT)

(72) Inventors: Robert Haase, San Pedro, CA (US); Stefan Karner, Klagenfurt (AT); Thomas Martin Feil, Villach (AT)

(21) Appl. No.: 18/813,928

(22) Filed: Aug. 23, 2024

(30) Foreign Application Priority Data
Sep. 21, 2023 (EP) 23198807

(51) Int. Cl. H01L 29/78; H01L 27/092; H01L 29/423; H01L 29/49; H01L 29/66

(52) U.S. Cl. CPC H10D 30/668; H10D 30/0297; H10D 64/513; H10D 64/663; H10D 84/85

(57) ABSTRACT

A semiconductor device includes a vertical power transistor having a plurality of power transistor cells. Each power transistor cell includes a source region at a first main surface of a semiconductor substrate, a drain region at a second main surface of the semiconductor substrate opposite the first main surface, a gate trench extending into the semiconductor substrate from the first main surface, a gate electrode in the gate trench and comprising doped polycrystalline silicon, and a dielectric material separating the gate electrode from the semiconductor substrate. An upper central part of each of the gate electrodes of the power transistor cells is occupied by a metal silicide region that adjoins the doped polycrystalline silicon. A method of producing the semiconductor device is also described.

### BACKGROUND

Power silicon technology for high performance DCDC systems typically utilizes an NMOS (n-type metal-oxide-semiconductor) power MOSFET (metal-oxide-semiconductor field-effect transistor) cells with heavily n-doped polysilicon gates. Integrating a low threshold CMOS (complementary metal-oxide-semiconductor) device requires the use of p-doped polysilicon gates for the PMOS (p-type metal-oxide-semiconductor) cells and n-doped polysilicon gates for the NMOS cells and the NMOS Power MOSFET. However, p-doped polysilicon is a rather high resistivity material, which can lead to rather high gate resistance and slow signal propagation especially as gate dimensions shrink for lower voltage high performance circuits. Also, boundaries between the NMOS and PMOS devices result in pn diodes in the complementary doped polysilicon lines.

Thus, there is a need for an improved power silicon technology that supports the integration of a CMOS device with a power transistor device on the same silicon die (chip).

### SUMMARY

According to an embodiment of a semiconductor device, the semiconductor device comprises: a vertical power transistor comprising a plurality of power transistor cells, wherein each of the power transistor cells comprises a source region at a first main surface of a semiconductor substrate, a drain region at a second main surface of the semiconductor substrate opposite the first main surface, a gate trench extending into the semiconductor substrate from the first main surface, a gate electrode in the gate trench and comprising doped polycrystalline silicon, and a dielectric material separating the gate electrode from the semiconductor substrate, wherein an upper central part of each of the gate electrodes of the power transistor cells is occupied by a metal silicide region that adjoins the doped polycrystalline silicon.

According to an embodiment of a method of producing a semiconductor device, the method comprises: forming a vertical power transistor having a plurality of power transistor cells, wherein each of the power transistor cells comprises a source region at a first main surface of a semiconductor substrate, a drain region at a second main surface of the semiconductor substrate opposite the first main surface, a gate trench extending into the semiconductor substrate from the first main surface, a gate electrode in the gate trench and comprising doped polycrystalline silicon, and a dielectric material separating the gate electrode from the semiconductor substrate; and forming a metal silicide region that adjoins the doped polycrystalline silicon in an upper central part of each of the gate electrodes of the power transistor cells.

Those skilled in the art will recognize additional features and advantages upon reading the following detailed description, and upon viewing the accompanying drawings.

### BRIEF DESCRIPTION OF THE DRAWINGS

The elements of the drawings are not necessarily to scale relative to each other. Like reference numerals designate corresponding similar parts. The features of the various illustrated embodiments can be combined unless they exclude each other. Embodiments are depicted in the drawings and are detailed in the description which follows.

FIG. 1 illustrates a partial cross-sectional view of a semiconductor device that includes a vertical power transistor and a CMOS device monolithically integrated in the same semiconductor die.

FIGS. 2A through 2M illustrate the partial cross-sectional views of the same part of the semiconductor device as in FIG. 1, during different stages of a method of producing the semiconductor device.

FIG. 3 illustrates a partial top plan view of the CMOS device, in the region of two (2) neighboring NMOS and PMOS cells.

### DETAILED DESCRIPTION

The embodiments described herein provide a power semiconductor technology that may support the monolithic integration of CMOS devices, by utilizing a metal silicide region in complimentarily doped polysilicon. Accordingly, p-doped polysilicon gates for PMOS cells and n-doped polysilicon gates for NMOS cells and a power FET include a metal silicide region that reduces the gate resistance of all devices and improves signal propagation delay. If no isolation is provided between the NMOS and PMOS cells of the CMOS device, including the metal silicide region in the gate electrodes of both CMOS cell types provides a connection across the pn-junctions/diodes at the boundaries of neighboring NMOS and PMOS cells. The power transistor integrated in the same semiconductor die as the CMOS device is formed from a plurality of power transistor cells, each cell including a gate trench and a gate electrode in the gate trench. The gate electrode of the power transistor cells comprises doped polycrystalline silicon. An upper central part of each gate electrode of the power transistor cells is occupied by a metal silicide region that adjoins the doped polycrystalline silicon.

The NMOS and PMOS cells of the CMOS device monolithically integrated in the same semiconductor die may form part or all of a gate driver that drives the power transistor. For example, in the case of a multi-stage driver, the NMOS and PMOS cells of the monolithically integrated CMOS device may form the last (output) stage of the gate driver. Some or all of the remaining driver stages may be monolithically integrated in the same semiconductor die as the last stage, or formed in a separate semiconductor die.

Including a metal silicide region in complimentary-doped polysilicon gates enables low and matched threshold NMOS and PMOS devices with a single gate oxide thickness shared with the main power transistor. This enables high performance, high frequency DCDC power supplies for energy efficient servers. Other circuit configurations may be realized by utilizing the metal silicide embodiments described herein.

Described next with reference to the figures are embodiments of a power semiconductor technology that supports the monolithic integration of CMOS devices, by utilizing a metal silicide region in complimentarily doped polysilicon gates. The embodiments are described in the context of Si (silicon) power semiconductor technology but may be applied to other power semiconductor technologies such as SiC (silicon carbide) or GaN on Si where the main power transistor is a GaN device with a CMOS driver integrated into a silicon substrate, for example.

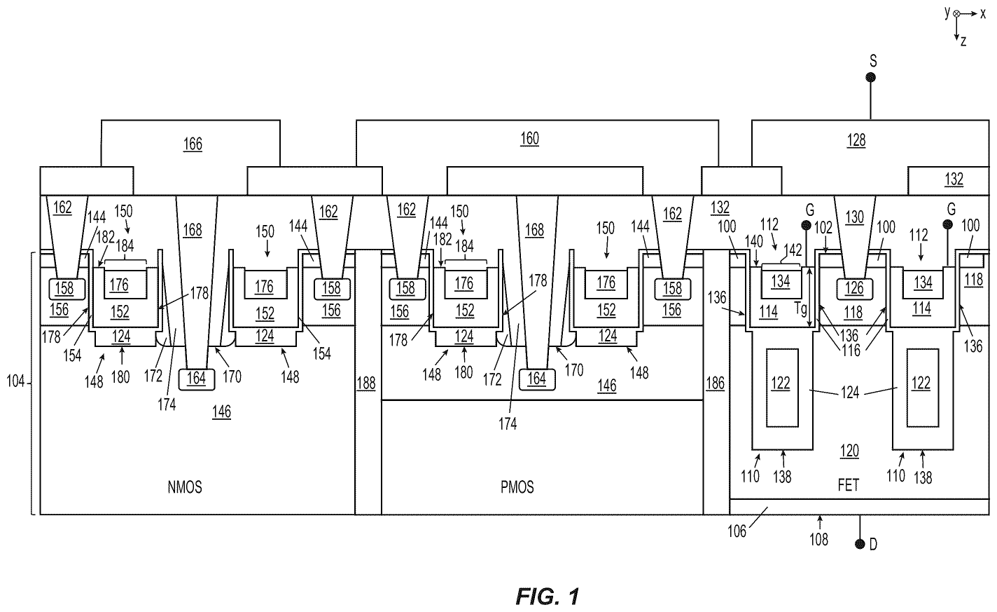

FIG. 1 illustrates a partial cross-sectional view of a semiconductor device that includes a vertical power transistor ‘FET’ and a CMOS device monolithically integrated in the same semiconductor die. The CMOS device may be the last (output) stage of a gate driver for the vertical power transistor, the entire gate driver, or another logic device used in conjunction with the vertical power transistor. The CMOS device includes an NMOS part ‘NMOS’ and a PMOS part ‘PMOS’. The CMOS device may include a single NMOS cell and a single PMOS cell or multiple NMOS cells and multiple PMOS cells. The vertical power transistor may include tens, hundreds, thousands or more power transistor cells. Other cell layouts and configurations are contemplated, and depend on the target application and requirements. In other words, the embodiments described herein are not intended to be limited to the specific cell layout and configuration illustrated.

The vertical power transistor includes a plurality of power transistor cells, two of which are shown in FIG. 1. Each cell of the vertical power transistor includes a source region 100 of a first conductivity type at a first main surface 102 of a semiconductor substrate 104, a drain region 106 of the first conductivity type at a second main surface 108 of the semiconductor substrate 104 opposite the first main surface 102, a gate trench 110 extending into the semiconductor substrate 104 from the first main surface 102, a gate electrode 112 in the gate trench 110 and comprising doped polycrystalline silicon 114, and a dielectric material 116 such as silicon oxide (e.g., thermally grown SiO₂) separating the gate electrode 112 from the semiconductor substrate 104. The drain region 106 is common to all power transistor cells in FIG. 1. The semiconductor substrate 104 may be a bulk Si material or may include one or more Si epitaxial layers grown on a bulk Si material. In another embodiment, the semiconductor substrate 104 comprises SiC.

Each vertical power transistor cell also includes a body region 118 of a second conductivity type opposite the first conductivity type. The source region 100 and the body region 118 of the same power transistor cell adjoin at least one sidewall of the corresponding gate trench 110. The source region 214 of each power transistor cell is separated from a (common) drift zone 120 of the first conductivity type by the corresponding body region 118. Each vertical power transistor cell may also include a field electrode/field plate 122 below the gate electrode 112 in each gate trench 110 and dielectrically insulated from the semiconductor substrate 104 by a field dielectric 124. The gate trenches 110 of the vertical power transistor may be ‘stripe-shaped’ in that the gate trenches 110 may have a longest linear dimension in a direction which runs in and out of the page in FIG. 1, parallel to the first main surface 102 of the semiconductor substrate 104 and transverse to the depth-wise direction (z direction in FIG. 1) of the semiconductor substrate 104.

The vertical power transistor is illustrated as a vertical power MOSFET in FIG. 1. However, the vertical power transistor instead may be an IGBT (Insulated gate bipolar transistor). In the case of an IGBT as the vertical power transistor, the same or similar MOS cells are used in conjunction with p-doped regions (not shown) at the second main surface 108 of the semiconductor substrate 104 to provide carrier flooding. Accordingly, the term ‘source region’ refers to a source region of a power MOSFET or an emitter region of an IGBT and the term ‘drain region’ refers to a drain region of a power MOSFET or a collector region of an IGBT.

The first conductivity is n-type and the second conductivity type is p-type for an n-channel device formed by the power transistor cells, whereas the first conductivity is p-type and the second conductivity type is n-type for a p-channel device formed by the power transistor cells. For either an n-channel device or a p-channel device, the source region 100 and the body region 118 form part of a transistor cell and the transistor cells are electrically connected in parallel between the source and drain terminals S, D of the power semiconductor device to form the vertical power transistor Q1.

The body regions 118 of the power transistor cells may include a body contact region 126 of the second conductivity type. The body contact regions 126 have a higher doping concentration than the body regions 118, to provide an ohmic connection with a source/emitter metallization 128 through a contact structure such as electrically conductive vias 130 that extend through a single or multi-layer interlayer dielectric 132 that separates the source metallization 128 from the semiconductor substrate 104. The source regions 100 of the vertical power transistor cells are also electrically connected to the source metallization 128 through the contact structure 130. A drain metallization (not shown in FIG. 1) electrically connected to the drain region 106 of the vertical power transistor may be provided at the opposite side of the semiconductor substrate 104 as the source metallization 128.

The gate electrodes 112 of the vertical power transistor cells are electrically connected to a gate terminal G of the power semiconductor device through, e.g., a gate metallization which is out of view in FIG. 1. The gate metallization may be part of a structured power metallization that also includes the source metallization 128. Such a structured power metallization may include a thick power metal layer that comprises Cu, AI, AlCu, AlSiCu, etc., a diffusion barrier and/or adhesion promoter such as Ti and/or TIN and/or W between the thick power metal layer and the interlayer dielectric 132.

An upper central part of each of the gate electrodes 112 of the power transistor cells is occupied by a metal silicide region 134 that adjoins the doped polycrystalline silicon part 114 of the gate electrode 112. In one embodiment, the vertical power transistor is a n-channel device and the doped polycrystalline silicon part 114 of each gate electrode 112 is n-doped. In another embodiment, the vertical power transistor is a p-channel device and the doped polycrystalline silicon part 114 of each gate electrode 112 is p-doped or n-doped.

In either case, the metal silicide region 134 that adjoins the doped polycrystalline silicon 114 in the upper central part of each gate electrode 112 may be spaced inward from the sidewalls 136 and the bottom 138 of each gate trench 110 of the power transistor cells. That is, part of the doped polycrystalline silicon part 114 may be interposed between the metal silicide region 134 and the sidewalls 136 and the bottom 138 of each gate trench 110. If the gate trenches 110 of the vertical power transistor include a field electrode/field plate 122 below the gate electrode 112 as shown in FIG. 1, then the metal silicide region 134 may be spaced upward from the part of the field dielectric 124 that vertically separates the gate electrode 112 from the field electrode/field plate 122. That is, part of the doped polycrystalline silicon 114 may separate the metal silicide region 134 from the part of the field dielectric 124 vertically interposed between the gate electrode 112 and the field electrode/field plate 122.

As shown in FIG. 1, an upper surface 140 of the doped polycrystalline silicon 114 may have a recess 142 that is laterally spaced inward from the sidewalls 138 of each gate trench 110 of the power transistor cells and the metal silicide region 134 may be formed along the sidewalls and the bottom of the recess 142 in each of the gate trenches 110. The metal silicide region 134 may comprise cobalt silicide, for example. Both oxide and nitride block the formation of cobalt silicide. Accordingly, at least part of the upper surface 140 of the doped polycrystalline silicon 114 must be free of dielectric material to define a window in which cobalt silicide can be formed on the doped polycrystalline silicon 114.

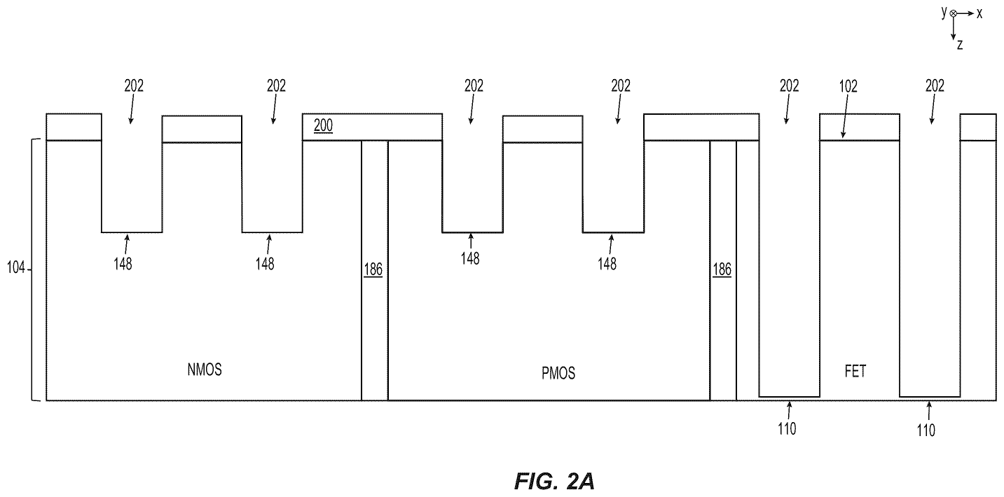

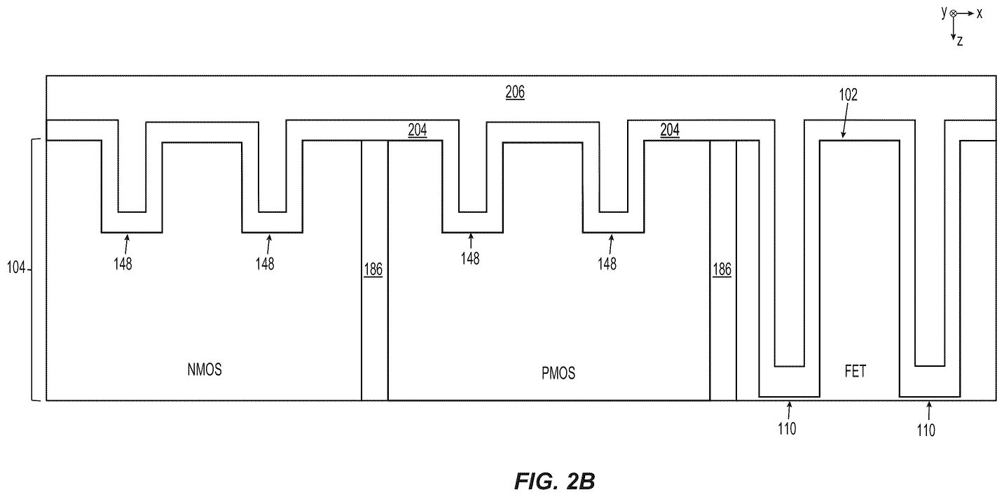

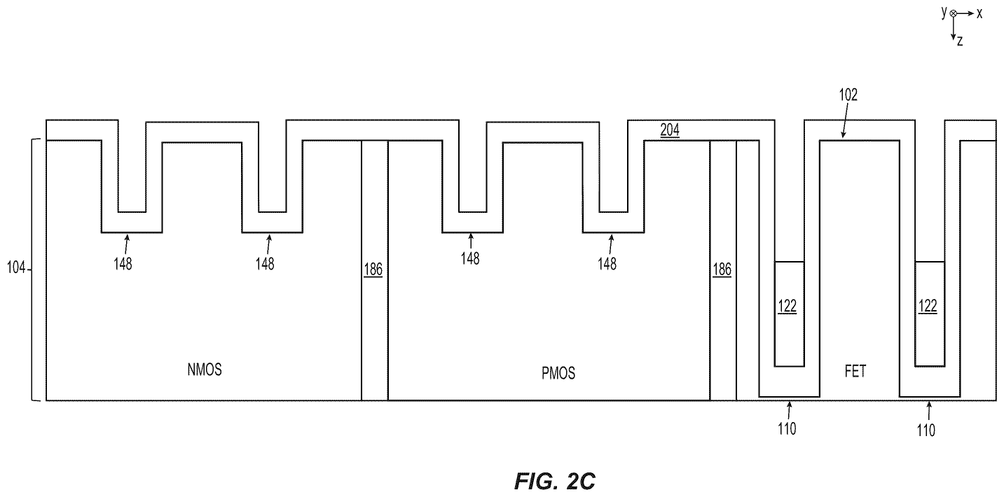

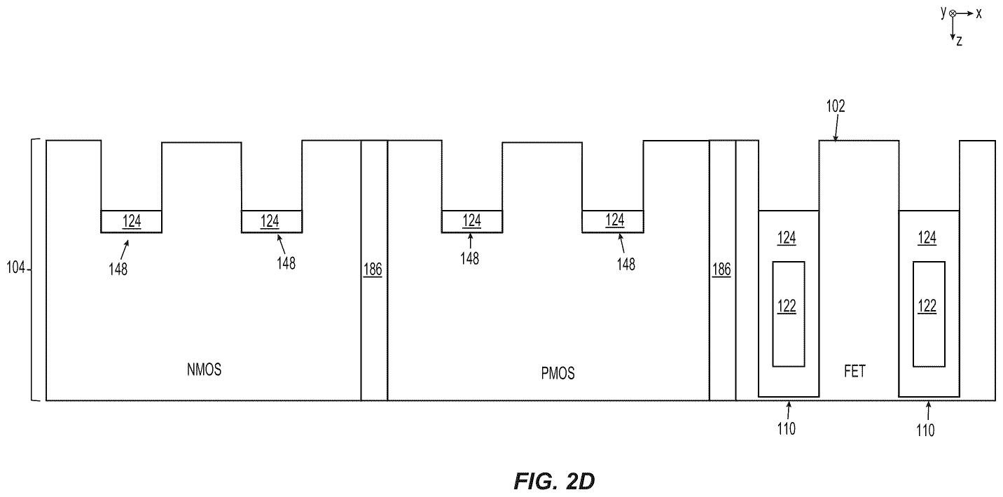

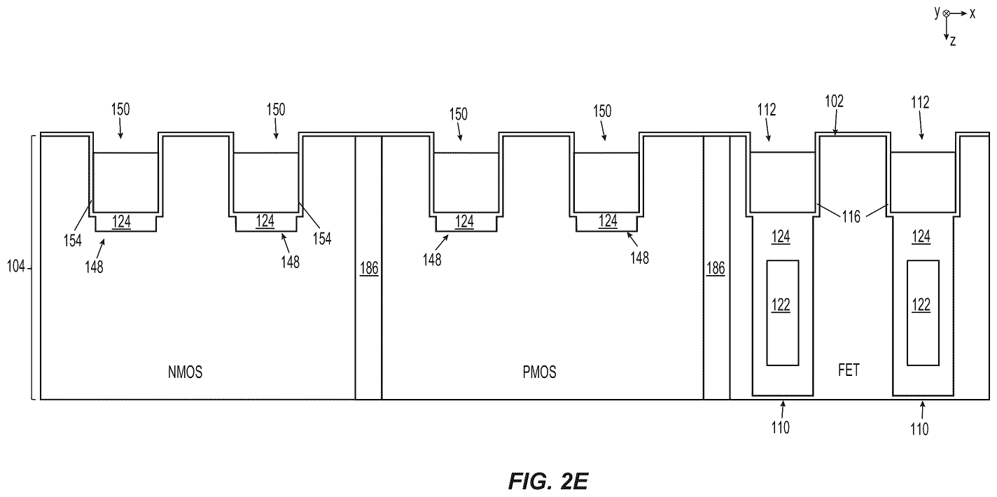

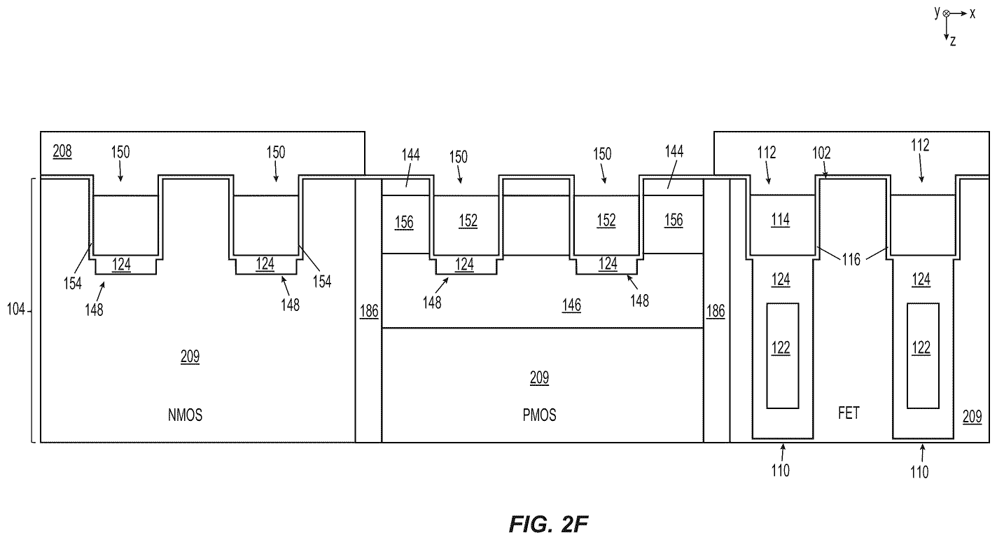

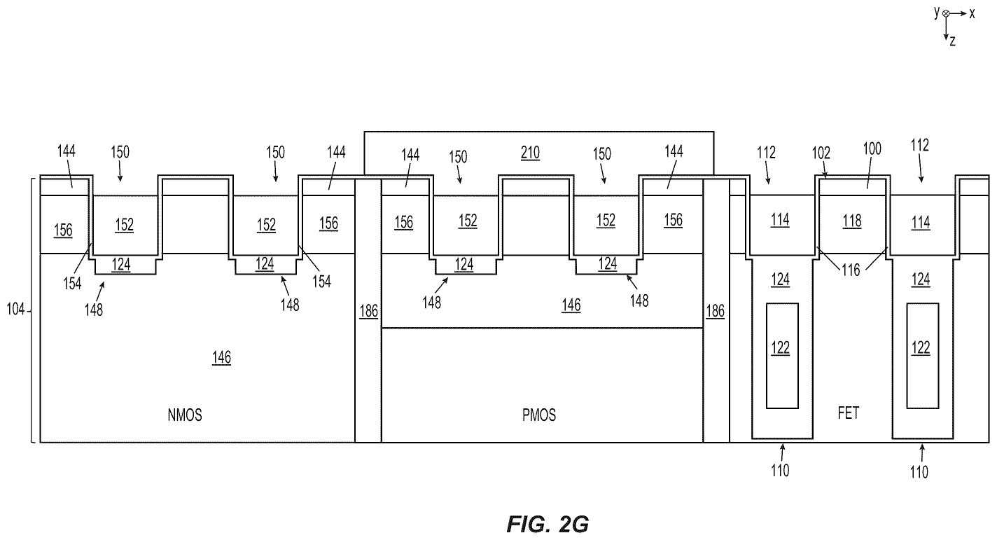

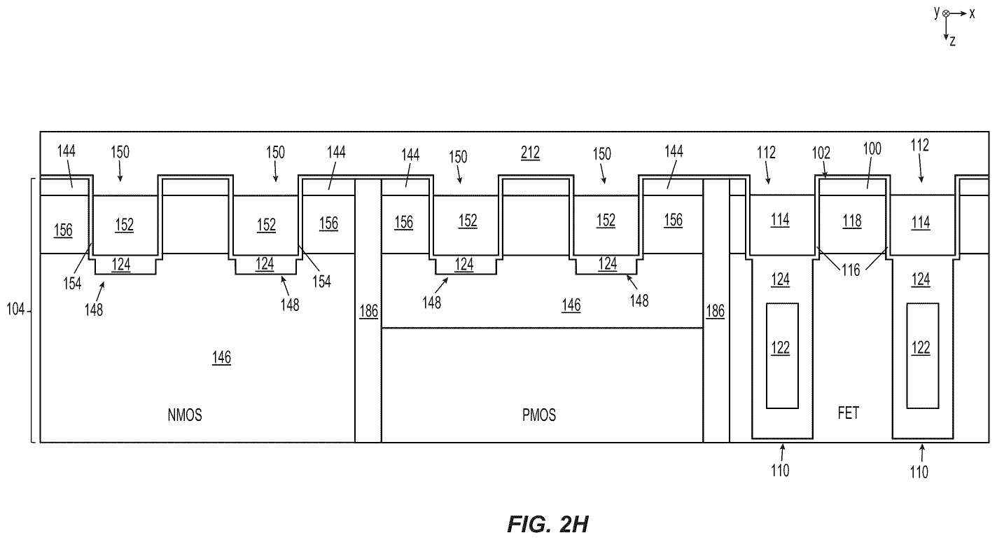

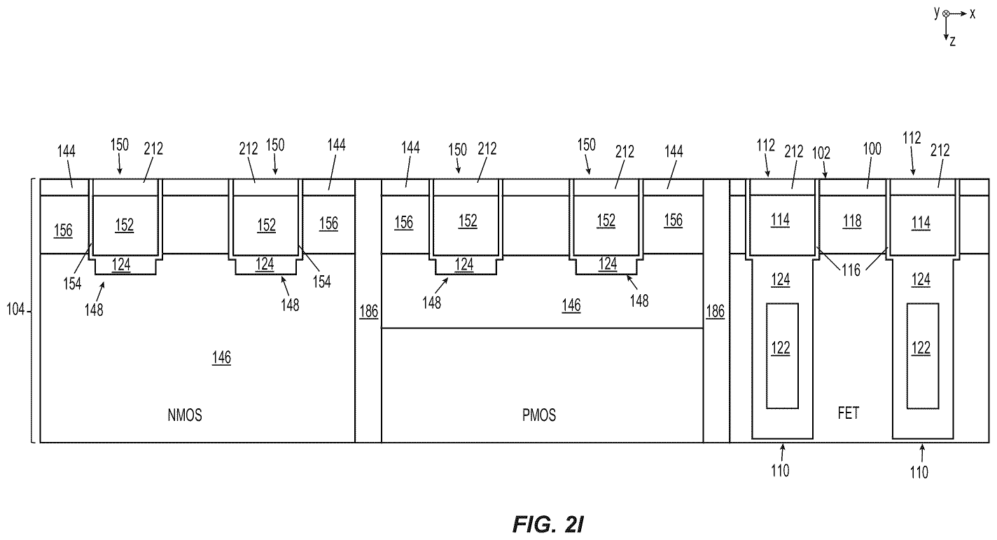

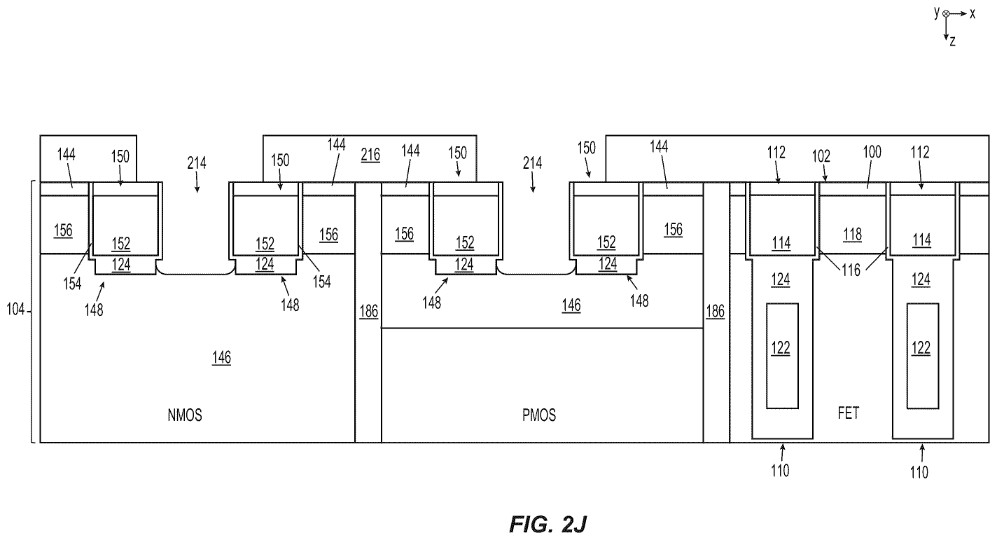

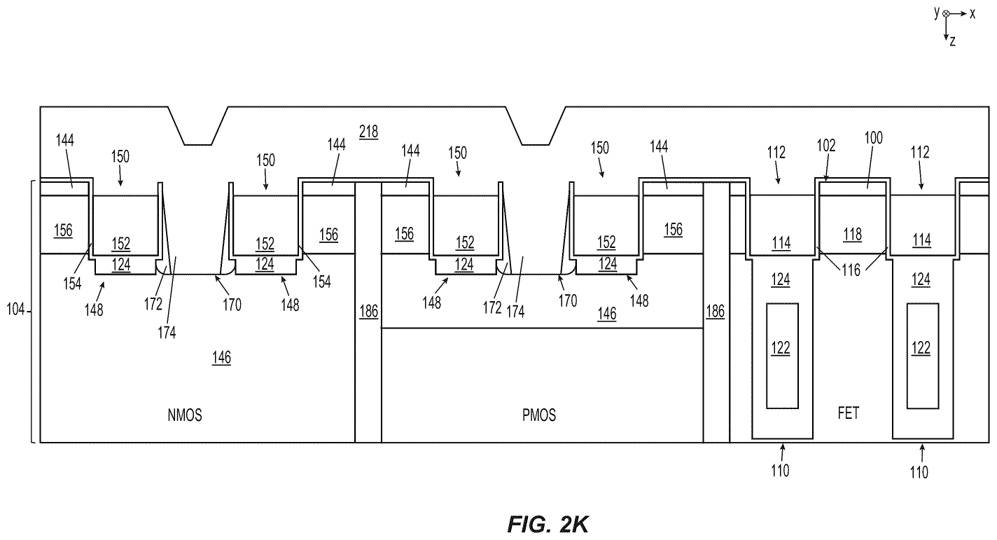

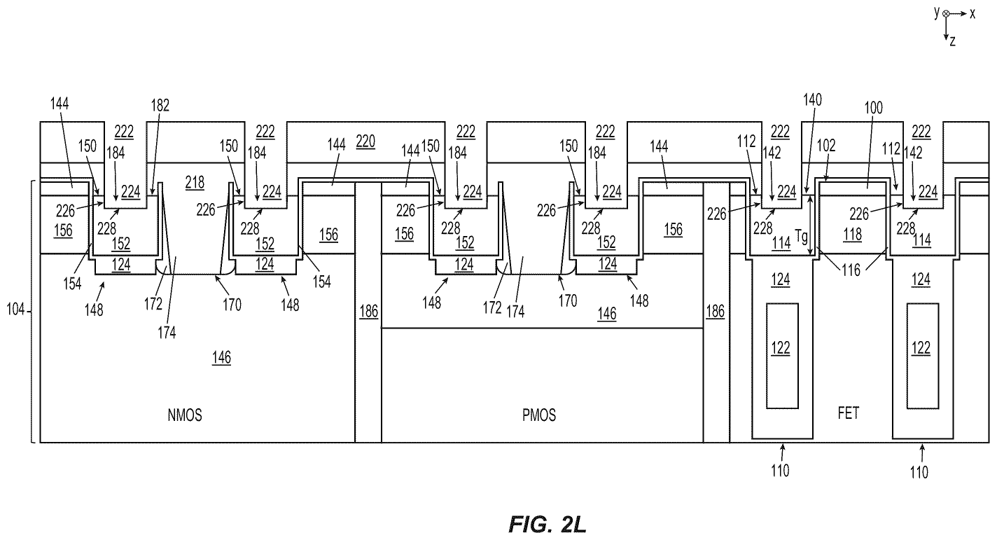

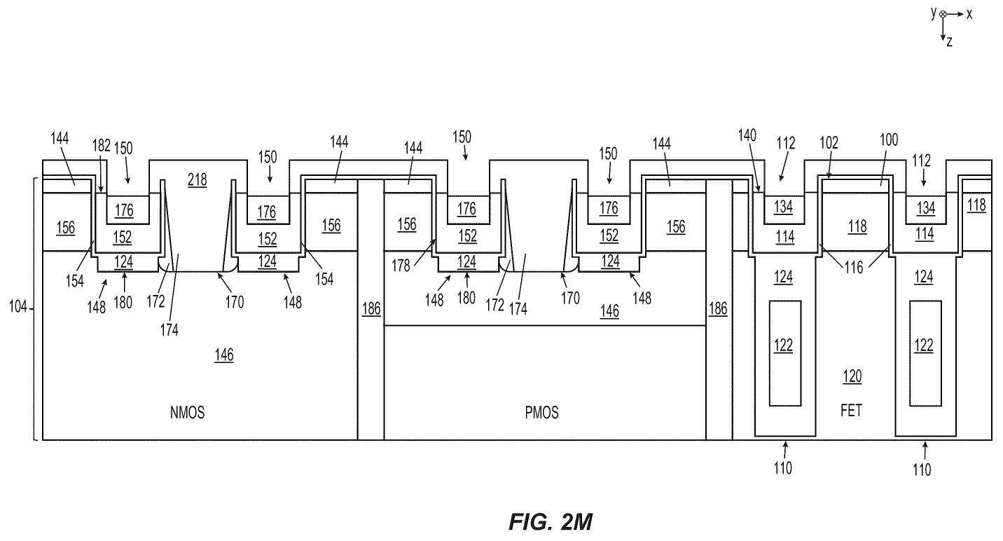

The dielectric widow opening process may involve over-etching of the doped polycrystalline silicon 114 to ensure no residual dielectric material remains in the target area, which results in the recess 142, e.g., as described in more detail later in connection with FIGS. 2A through 2M. Alternatively, the target area of the upper surface 140 of the doped polycrystalline silicon 114 can be cleaned with minimal or even no over etching/recessing of the doped polycrystalline silicon 114. In either case, cobalt silicide can then be formed on the dielectric-free part of the doped polycrystalline silicon 114, including on the exposed sidewalls and bottom of the recess 142 in the doped polycrystalline silicon 114 if the recess 142 is present.

In one embodiment, for each of the gate electrodes 112 of the power transistor cells, the recess 142 etched into the doped polycrystalline silicon 114 is in a range of up to 25% of a thickness Tg of the gate electrode 112. Separately or in combination, the recess 142 may be in a range of, e.g., 1 nm to 100 nm, 5 nm to 70 nm, 10 nm to 50 nm, etc. below the first main surface 102 of the semiconductor substrate 104.

As shown in FIG. 1, the upper surface 140 of each gate electrode 112 of the power transistor cells may be recessed below the first main surface 102 of the semiconductor substrate 104. Alternatively, the upper surface 140 of each gate electrode 112 may be coplanar with the first main surface 102 of the semiconductor substrate 104. Whether or not the upper surface 140 of each gate electrode 112 is coplanar with the first main surface 102 of the semiconductor substrate 104 depends on the processing employed, e.g., illustrated in FIGS. 2A through 2M. Also as shown in FIG. 1, the upper surface 140 of each gate electrode 112 of the power transistor cells may be completely covered only by oxide. In FIG. 1, the covering oxide is the interlayer dielectric 132. The covering oxide may include a single layer or multiple layers of oxide, and may comprise the same oxide composition throughout (e.g., deposited oxide) or a combination of oxide compositions (e.g., thermally grown oxide and deposited oxide). One or more layers of a different dielectric material such as silicon nitride may be formed on the covering oxide.

As described above, the semiconductor device may include a CMOS device such as a gate driver or part of a gate driver monolithically integrated in the same semiconductor substrate 104 as the vertical power transistor. The CMOS device includes one or more PMOS cells and one or more NMOS cells. Each PMOS cell and each NMOS cell of the CMOS device includes a source region 144 at the first main surface 102 of the semiconductor substrate 104, a drift region 146, a gate trench 148 extending into the semiconductor substrate 104 from the first main surface 102, a gate electrode 150 in the gate trench 148 and comprising doped polycrystalline silicon 152, and a dielectric material 154 such as silicon oxide (e.g., thermally grown SiO₂) separating the gate electrode 150 from the semiconductor substrate 104.

Each NMOS and PMOS cell of the CMOS device also includes a body region 156 of the opposite conductivity type as the source region 144 of the same CMOS cell type. The source region 144 and the body region 156 of the same CMOS cell type adjoin at least one sidewall of the corresponding gate trench 148. The gate trenches 148 of the CMOS device may be stripe-shaped. For the NMOS cells, the source, drift and drain regions 144, 146, 164 are n-type and the body region 156 is p-type. Conversely for the PMOS cells, the source, drift and drain regions 144, 146, 164 are p-type and the body region 156 is n-type. The drift region 146 of the PMOS cells may be part of a p-well if the semiconductor substrate 104 has an n-type background doping.

The body regions 156 of the CMOS cells may include a body contact region 158 of the same conductivity type as the body region 156 for the same CMOS cell type (e.g., p+ for the NMOS cells and n+ for the PMOS cells). The body contact regions 158 have a higher doping concentration than the respective body regions 156, to provide an ohmic connection with a source metallization 160 through a contact structure such as electrically conductive vias 162 that extend through the interlayer dielectric 132 that separates the source metallization 160 from the semiconductor substrate 104. Only the PMOS source metallization 160 is visible in FIG. 1.

Highly doped drain regions 164 of each CMOS cell type (e.g., n+ for the NMOS cells and p+ for the PMOS cells) provide an ohmic connection with a drain metallization 166 through a contact structure such as electrically conductive vias 168 that extend through the interlayer dielectric 132. Only the NMOS drain metallization 166 is visible in FIG. 1.

The drain connection to each NMOS and PMOS cell of the CMOS device is made at the frontside of the semiconductor substrate 104 in FIG. 1, as opposed to the vertical power transistor drain connection which is made at the substrate backside. For example, adjacent gate trenches 148 of the same CMOS cell type may be laterally separated from one another by a dielectric mesa 170 and a contact 168 may extend through the dielectric mesa 170 to or into the semiconductor substrate 104 to provide the drain connection. The dielectric mesa 170 may include, e.g., a TEOS (tetraethoxysilane) sidewall spacer 172 and an oxide filler 174. Other cell layouts and configurations are contemplated, and depend on the target application and requirements. For example, although FIG. 1 shows a recessed drain configuration for the CMOS device, other drain configurations are possible, e.g., the dielectric mesa 170 may be omitted and the source and drain regions 144, 164 of the CMOS cells may be coplanar at the first main surface 102 of the semiconductor substrate 104.

The gate electrodes 150 of the CMOS cells are electrically connected to a gate metallization which is out of view in FIG. 1. The CMOS metallization may be part of the same structured power metallization used for the vertical power transistor.

Like the vertical power transistor cells, the upper central part of each CMOS gate electrode 150 is occupied by a metal silicide region 176 that adjoins the doped polycrystalline silicon part 152 of the CMOS gate electrode 150. In one embodiment, the vertical power transistor is a n-channel device, the doped polycrystalline silicon 134 in each gate trench 110 of the power transistor cells is n-doped, the doped polycrystalline silicon 152 in the gate trench 148 of each NMOS cell of the CMOS device is n-doped, and the doped polycrystalline silicon 152 in the gate trench 148 of each PMOS cell of the CMOS device is p-doped or n-doped. In another embodiment, the vertical power transistor is a p-channel device, the doped polycrystalline silicon 134 in each gate trench 110 of the power transistor cells is p-doped or n-doped, the doped polycrystalline silicon 152 in the gate trench 148 of each NMOS cell of the CMOS device is n-doped, and the doped polycrystalline silicon 152 in the gate trench 148 of each PMOS cell of the CMOS device is p-doped or n-doped.

In either case, providing the metal silicide region 176 in the CMOS gate electrodes 150 lowers the gate resistance for both CMOS device types, which is particularly beneficial for p-doped polycrystalline silicon since p-doped polycrystalline silicon is more resistive than n-doped polycrystalline silicon for equivalent doping levels. However, p- or n-doping of the polycrystalline silicon in the CMOS gate electrodes 150 may be performed during the source implant which can lead to higher gate resistance than if deposited p- or n-doped polysilicon is used. Accordingly, providing the metal silicide region 176 in the gate electrodes 150 of the NMOS cells can be beneficial. Also, narrower cell dimensions results in increased gate resistance which can be lowered by including metal or silicide in the CMOS gate electrodes 150.

If the metal silicide regions 176 of the CMOS device and the metal silicide regions 134 of the vertical power transistor are formed via common processing steps, e.g., as illustrated in FIGS. 2L and 2M, then the metal silicide regions 176 of the CMOS device may have the same configuration as the metal silicide regions 134 of the vertical power transistor. For example, the metal silicide region 176 that adjoins the doped polycrystalline silicon part 152 of each CMOS gate electrode 150 may be spaced inward from the sidewalls 178 and the bottom 180 of each gate trench 150 of the CMOS cells. In another example, the upper surface 182 of the doped polycrystalline silicon 152 may have a recess 184 that is laterally spaced inward from the sidewalls 178 of each CMOS gate trench 148 and the metal silicide region 176 may be formed along the sidewalls and the bottom of the recess 184 in each of the CMOS gate trenches 148.

An isolation structure 186 ensures adequate isolation in the semiconductor substrate 104 between the CMOS device and the vertical power transistor. Another isolation structure 188 may be provided between the NMOS and PMOS parts of the CMOS device. The isolation structures 186, 188 may include, e.g., a trench filled with an electrically insulative material such as an oxide. For example, the isolation structure 186 between the CMOS device and the vertical power transistor may be a deep trench isolation structure that extends through the entire depth of the semiconductor substrate 104. The isolation 188 between the NMOS and PMOS parts of the CMOS device need not be all the way through the semiconductor substrate 104. For example, junction isolation may be used where a p-well or versions of a deeper vertical FET trench can be used as an isolation structure. In this case, gate and source features of the trench are not connected.

FIGS. 2A through 2M illustrate the partial cross-sectional views of the same part of the semiconductor device as in FIG. 1, during different stages of a method of producing the semiconductor device.

FIG. 2A shows the semiconductor substrate 104 after the isolation structure 186 is formed in the semiconductor substrate 104 between the CMOS device and the vertical power transistor, and an optional isolation structure 188 is formed in the semiconductor substrate 104 between the NMOS and PMOS parts of the CMOS device. FIG. 2A also shows the semiconductor substrate 104 after a hard mask layer 200 such as a deposited or thermally grown oxide is formed on the first main surface 102 of the semiconductor substrate 104. The hard mask layer 200 is etched, e.g., using a lithography process to form openings 202 in the hard mask layer 200. The device gate trenches 110, 148 are then etched into the first main surface 102 of the semiconductor substrate 104 through the openings 202 in the hard mask layer 200.

If the gate trenches 110 of the vertical power transistors extend deeper into the semiconductor substrate 104 than the CMOS gate trenches 148, e.g., to accommodate a field electrode/field plate 122, both types of device gate trenches 110, 148 can be etched to a first depth which corresponds to the depth of the CMOS gate trenches 148. The CMOS gate trenches 148 can then be covered, e.g., using a lithography process and the gate trenches 110 of the vertical power transistor are etched deeper into the semiconductor substrate 104 while the CMOS gate trenches 148 are covered.

FIG. 2B shows the semiconductor substrate 104 after the hard mask layer 200 is removed and a field oxide 204 is formed over the first main surface 102 of the semiconductor substrate 104. The field oxide 204 can be thermally grown or deposited SiO₂, or both, for example. Another dielectric material may be used for the field oxide 204. Polysilicon (i.e. polycrystalline Si) 206 is then deposited on the field oxide 204. The polysilicon 206 may be heavily doped, e.g., with phosphorous.

FIG. 2C shows the semiconductor substrate 104 after the polysilicon 206 is removed from the CMOS gate trenches 148 and recessed in the power transistor gate trenches 110 to define the optional field electrode/field plates 122. The polysilicon 206 can be removed from the first main surface 102 of the semiconductor substrate 104 by CMP (chemical mechanical polishing), stopping on the field oxide 204. A plasma recess of the polysilicon 206 can then be performed to the desired depth for the power transistor field electrodes/field plates 122. The recess depth is chosen so as to sufficiently remove all polysilicon 206 from the CMOS gate trenches 148. The field electrodes/field plates 122 are shown in FIG. 2C as comprising only polysilicon 206. However, the field electrodes/field plates 122 instead may be made of a metal, silicide, TiN, or a combination thereof.

FIG. 2D shows the semiconductor substrate 104 after etching of the exposed field oxide 204 and a subsequent oxide formation process. The oxide formation process may include HDP (high density plasma) deposition of an oxide to fill all device trenches 110, 148 followed by a planarization process such as CMP that stops on the semiconductor mesas between the gate trenches 110, 148. A wet recess etch of the oxide in the trenches 110, 148 is then performed to a depth desired for the power transistor channel and to provide dielectric isolation from the field electrode/field plate 122, resulting in the field oxide 124 shown in FIG. 1. The field oxide 124 can remain at the bottom of the CMOS gate trenches 148, to cover a transistor drift region along this part of the CMOS gate trenches 148. The thicker oxide 124 in the CMOS device region reduces capacitance between gate and drain (Cgd).

FIG. 2E shows the semiconductor substrate 104 after formation of the gate oxide 116, 154 and the gate electrodes 112, 150 in both device regions. According to this embodiment, the gate oxide 116, 154 and the gate electrodes 112, 150 of both device types are formed using common processing. The gate oxide 116, 154 may be formed by depositing or thermally growing oxide. The gate electrodes 112, 150 may be formed by depositing polycrystalline or amorphous silicon over the first main surface 102 of the semiconductor substrate 104 and in the gate trenches 110, 148 of both device types.

The polycrystalline or amorphous silicon is then removed outside the gate trenches 110, 148, e.g., via CMP. Optionally, a recess etch may be performed to recess the polycrystalline or amorphous silicon in the gate trenches 110, 148 of one or both device types below the first main surface 102 of the semiconductor substrate 104. For example, a plasma etch may be used which is selective to SiO₂ so that the gate oxide material remains on the first main surface 102 of the semiconductor substrate 104 between the gate trenches 110, 148. The polycrystalline or amorphous silicon may be recessed about 100 nm below the first main surface 102 of the semiconductor substrate 104, for example, to optimize the devices and improve manufacturability. Alternatively, the polycrystalline or amorphous silicon is not recessed below the first main surface 102 of the semiconductor substrate 104.

FIG. 2F shows the semiconductor substrate 104 after the device regions of the PMOS cells are formed. An implant mask 208 such as a photoresist that is thick enough to block the high energy implant protects both the power transistor region and the NMOS part of the CMOS device. A high energy implant of a p-type dopant species such as boron is then performed with sufficient energy to counter dope an n-type epitaxial layer 209 to p-type and a dose optimised to yield the desired breakdown voltage, to define the drift/p-well region 146 of each PMOS cell. An n-type dopant species such as arsenic or phosphorous is implanted to define the body region 156 of each PMOS cell. A high dose implantation of a p-type dopant species such as boron or BF₂ defines the source region 144 and dopes the polysilicon/amorphous Si gate electrode 150 to be p-type in each PMOS cell. The implant mask 208 is then removed and an anneal is performed to drive in the p-type dopant, thereby doping the polycrystalline or amorphous silicon 152 in the PMOS gate trenches 148. Alternatively, the polycrystalline or amorphous silicon 152 in the PMOS gate trenches 148 may be n-doped.

FIG. 2G shows the semiconductor substrate 104 after the device regions of the CMOS cells and of the power transistor cells are concurrently formed. According to this embodiment, the gate electrode 112 of each power transistor cell and the gate electrode 150 of each NMOS cell are concurrently doped with a dopant species of the first doping type while each PMOS cell is masked. More particularly, an implant mask 210 such as a photoresist may protect the PMOS part of the CMOS device. The drift region 146 of each NMOS cell and the drift region 120 of each power transistor cell may be realized by the background doping of the semiconductor substrate 104, for example. A p-type dopant species such as boron or BF₂ is implanted to define the body region 156 of each NMOS cell and the body region 118 of each power transistor cell. A high dose implantation of an n-type dopant species such as arsenic or phosphorous defines the source region 144 of each NMOS cell and the source region 100, and dopes the polysilicon/amorphous Si gate electrode 112 to be N-type in each power transistor cell. The implant mask 210 is then removed and an anneal is performed to drive in the n-type dopant, thereby doping the polycrystalline or amorphous silicon 152 in the NMOS gate trenches 148 and the doped polycrystalline or doped amorphous silicon 114 in the power transistor gate trenches 110. The drain region 106 of the vertical power transistor is out of view and can be formed earlier or later.

FIG. 2H shows the semiconductor substrate 104 after an oxide 212 is deposited over the first main surface 102 of the semiconductor substrate 104. If the gate electrodes 112, 150 were previously recessed, e.g., as shown in FIG. 2E, the oxide 212 fills the recesses in the gate electrodes 112, 150.

FIG. 2I shows the semiconductor substrate 104 after the oxide 212 is planarized, e.g., via CMP. If the gate electrodes 112, 150 were previously recessed, e.g., as shown in FIG. 2E, the CMP stops on the semiconductor mesas between the gate trenches 110, 148.

FIG. 2J shows the semiconductor substrate 104 after etching the semiconductor substrate 104 to form a recess 214 between adjacent gate trenches 148 of the same cell type of the CMOS device. An etch mask 216 such as a photoresist exposes drain mesas and protects source mesas in the CMOS device area, and also protects the vertical power transistor area. A selective isotropic silicon plasma etch such as SF₆ can be used and which is highly selective to oxide which protects the CMOS gate dielectric material 154 from the top and sides. The etch mask 216 is then removed.

FIG. 2K shows the semiconductor substrate 104 after filling the recesses 214 in the CMOS device area and covering the first main surface 102 of the semiconductor substrate 104 with a dielectric material 218. The recess fill process may include TEOS deposition to form a sidewall spacer 172 that is followed by deposition of an oxide filler 174. The oxide filler 174 can be formed by depositing USG (undoped silicate glass) and HDP oxide.

FIG. 2L shows the semiconductor substrate 104 after planarizing an upper surface of the dielectric material 218 that faces away from the semiconductor substrate 104 to form the dielectric mesas in the recesses between the adjacent gate trenches 148 of the same CMOS (NMOS or PMOS) cell type. For example, the upper surface of the dielectric material 218 can be planarized by a timed CMP process that leaves a thin oxide layer (e.g., 20 nm to 150 nm) over the semiconductor mesas between adjacent gate trenches 110, 148. The planarized upper surface of the dielectric material 218 is then covered with a photoresist 220 having openings 222 that are vertically aligned with the gate electrodes 112 of the vertical power transistor and the gate electrodes 150 of the CMOS device. Alignment marks may be used to ensure the vertical alignment, for example.

Openings are then formed in the dielectric material 218 that are vertically aligned with the openings 222 of the photoresist 220. Optionally, the exposed gate electrodes 112 of the vertical power transistor and the gate electrodes 150 of the CMOS device may be recessed through the openings 222 of the photoresist 220 and the openings 224 of the dielectric material, to ensure no residual dielectric material remains in the desired area targeted for metal silicide formation. According to this embodiment, a recess 142 is formed in the upper central part of the doped polycrystalline or doped amorphous silicon 114 of each power transistor gate electrode 112 and in the upper central part of the doped polycrystalline or doped amorphous silicon 152 of each CMOS gate electrode 150. The recess 142 in the vertical power transistor part and the recess 184 in the CMOS part may be in a range of up to 25% of a thickness Tg of the respective gate electrode 112, 150. Separately or in combination, the recesses 142, 184 may be in a range of 1 nm to 100 nm, 5 nm to 70 nm, 10 nm to 50 nm, etc. below the first main surface 102 of the semiconductor substrate 104. Alternatively, the target area of the upper surface 140 of the doped polycrystalline or doped amorphous silicon 114, 152 can be cleaned with minimal or even no over etching/recessing of the doped polycrystalline or doped amorphous silicon 114, 152.

FIG. 2M shows the semiconductor substrate 104 after removing the photoresist 220 and then forming the metal silicide regions 134, 176 in the corresponding gate trench 110, 148. The metal silicide regions 134, 176 may be formed by depositing cobalt over the first main surface 102 of the semiconductor substrate 104 such that the cobalt comes into contact with the dielectric-free part of the power transistor gate electrodes 112 and the dielectric-free part of the CMOS gate electrodes 150. As explained above, the dielectric-free part of the power transistor gate electrodes 112 and the dielectric-free part of the CMOS gate electrodes 150 may or may not be recessed. If recessed as shown in FIG. 2L, the recess 142, 184 is laterally spaced inward from the sidewalls of the corresponding gate trench 110, 148 and the cobalt is deposited along the sidewalls 226 and the bottom 228 of the recess 142, 184 in each gate trench 110, 148. Otherwise, each gate electrode 112, 150 has a planar upper surface 140, 182 and the cobalt is deposited along the planar upper surface 140, 182 of each gate electrode 112, 150. In either case, the cobalt is then annealed to form the metal silicide regions 134, 176.

In one embodiment, the metal silicide regions 134, 176 are formed in the upper central part of the power transistor gate electrodes 112 and in the upper central part of the CMOS gate electrodes 150 by recessing the power transistor gate electrodes 112 and the CMOS gate electrodes 150, e.g., as shown in FIG. 2L, depositing cobalt over the first main surface 102 of the semiconductor substrate 104 such that the cobalt comes into contact with the recessed part 142 of each gate electrode 112 of the vertical power transistor and the recessed part 184 of each gate electrode 150 of the CMOS device, and depositing titanium or TIN on the cobalt. A first low temperature anneal process (e.g., e.g. in a range between 550° C. to 650° C.) is then performed in a nitrogen ambient. The first anneal process yields CoSi in contact with the recessed part 142 of each gate electrode 112 of the vertical power transistor and the recessed part 184 of each gate electrode 150 of the CMOS device. The first anneal process also yields a TiN layer on the CoSi. The TiN layer and unreacted Co are removed using a suitable wet etch process. A second anneal process is then performed at a higher temperature than the first anneal process, but less than 900° C. to form lower resistivity CoSi₂.

After forming the metal silicide regions 134, 176, the source, body and drain contacts shown in FIG. 1 are then formed. For example, the interlayer dielectric 132 is completed, e.g., by depositing BPSG (borophosphosilicate glass). The interlayer dielectric 132 is then planarized, e.g., via CMP. Contact lithography, etching and metal deposition processes are then performed to form the desired contacts shown in FIG. 1. Other cell layouts and configurations are contemplated, and depend on the target application and requirements. In other words, the embodiments described herein are not intended to be limited to the specific cell layout and configuration illustrated.

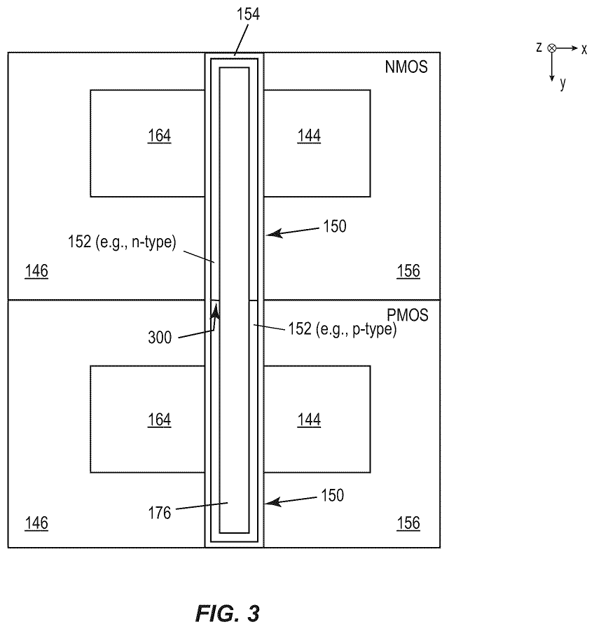

FIG. 3 illustrates a partial top plan view of the CMOS device, in the region of two (2) neighboring NMOS and PMOS cells. In FIG. 3, no isolation is provided between the NMOS and PMOS cells of the CMOS device. According to this embodiment, the metal silicide region 176 that occupies the upper central part of each of the gate electrodes 150 of the CMOS device provides a connection across the pn-junction/diode 300 at the boundary of the neighboring NMOS and PMOS cells.

Although the present disclosure is not so limited, the following numbered examples demonstrate one or more aspects of the disclosure.
Example 1. A semiconductor device, comprising: a vertical power transistor comprising a plurality of power transistor cells, wherein each of the power transistor cells comprises a source region at a first main surface of a semiconductor substrate, a drain region at a second main surface of the semiconductor substrate opposite the first main surface, a gate trench extending into the semiconductor substrate from the first main surface, a gate electrode in the gate trench and comprising doped polycrystalline silicon, and a dielectric material separating the gate electrode from the semiconductor substrate, wherein an upper central part of each of the gate electrodes of the power transistor cells is occupied by a metal silicide region that adjoins the doped polycrystalline silicon.
Example 2. The semiconductor device of example 1, wherein the vertical power transistor is a n-channel device, and wherein the doped polycrystalline silicon is n-doped.
Example 3. The semiconductor device of example 1, wherein the vertical power transistor is a p-channel device, and wherein the doped polycrystalline silicon is p-doped or n-doped.
Example 4. The semiconductor device of any of examples 1 through 3, wherein the metal silicide region is spaced inward from sidewalls and a bottom of each of the gate trenches of the power transistor cells.
Example 5. The semiconductor device of any of examples 1 through 4, wherein an upper surface of the doped polycrystalline silicon has a recess that is laterally spaced inward from sidewalls of each of the gate trenches of the power transistor cells, and wherein the metal silicide region is formed along sidewalls and a bottom of the recess in each of the gate trenches of the power transistor cells.
Example 6. The semiconductor device of example 5, wherein for each of the gate electrodes, the recess is in a range of up to 25% of a thickness of the gate electrode.
Example 7. The semiconductor device of example 5 or 6, wherein for each of the gate electrodes, the recess is in a range of 10 nm to 100 nm below the first main surface of the semiconductor substrate.
Example 8. The semiconductor device of any of examples 1 through 7, further comprising: a CMOS (complementary metal-oxide-semiconductor) device monolithically integrated in the same semiconductor substrate as the vertical power transistor and comprising one or more PMOS cells and one or more NMOS cells, wherein each PMOS cell and each NMOS cell of the CMOS device comprises a source region at the first main surface, a drift region, a gate trench extending into the semiconductor substrate from the first main surface, a gate electrode in the gate trench and comprising doped polycrystalline silicon, and a dielectric material separating the gate electrode from the semiconductor substrate, wherein an upper central part of each of the gate electrodes of the CMOS device is occupied by a metal silicide region that adjoins the doped polycrystalline silicon.
Example 9. The semiconductor device of example 8, wherein adjacent gate trenches of a same cell type of the CMOS device are laterally separated from one another by a dielectric mesa, and wherein a contact extends through the dielectric mesa to or into the semiconductor substrate to provide a drain connection.
Example 10. The semiconductor device of example 8 or 9, wherein the vertical power transistor is a n-channel device, wherein the doped polycrystalline silicon in each of the gate trenches of the power transistor cells is n-doped, wherein the doped polycrystalline silicon in the gate trench of each NMOS cell of the CMOS device is n-doped, and wherein the doped polycrystalline silicon in the gate trench of each PMOS cell of the CMOS device is p-doped or n-doped.
Example 11. The semiconductor device of example 8 or 9, wherein the vertical power transistor is a p-channel device, wherein the doped polycrystalline silicon in each of the gate trenches of the power transistor cells is p-doped or n-doped, wherein the doped polycrystalline silicon in the gate trench of each NMOS cell of the CMOS device is n-doped, and wherein the doped polycrystalline silicon in the gate trench of each PMOS cell of the CMOS device is p-doped or n-doped.
Example 12. The semiconductor device of any of examples 8 through 11, wherein an upper surface of the doped polycrystalline silicon has a recess that is laterally spaced inward from sidewalls of each of the gate trenches of both the vertical power transistor and the CMOS device, and wherein the metal silicide region is formed along sidewalls and a bottom of the recess in each of the gate trenches of both the vertical power transistor and the CMOS device.
Example 13. The semiconductor device of any of examples 8 through 12, wherein the metal silicide region that occupies the upper central part of the gate electrode of neighboring NMOS and PMOS cells provides a connection across a pn-junction at a boundary of the neighboring NMOS and PMOS cells.
Example 14. The semiconductor device of any of examples 1 through 13, wherein an upper surface of each of the gate electrodes is coplanar with the first main surface of the semiconductor substrate.
Example 15. The semiconductor device of any of examples 1 through 13, wherein an upper surface of each of the gate electrodes is recessed below the first main surface of the semiconductor substrate.
Example 16. The semiconductor device of any of examples 1 through 15, wherein an upper surface of each of the gate electrodes is completely covered only by oxide.
Example 17. A method of producing a semiconductor device, the method comprising: forming a vertical power transistor having a plurality of power transistor cells, wherein each of the power transistor cells comprises a source region at a first main surface of a semiconductor substrate, a drain region at a second main surface of the semiconductor substrate opposite the first main surface, a gate trench extending into the semiconductor substrate from the first main surface, a gate electrode in the gate trench and comprising doped polycrystalline silicon, and a dielectric material separating the gate electrode from the semiconductor substrate; and forming a metal silicide region that adjoins the doped polycrystalline silicon in an upper central part of each of the gate electrodes of the power transistor cells.
Example 18. The method of example 17, further comprising: monolithically integrating a CMOS (complementary metal-oxide-semiconductor) device in the same semiconductor substrate as the vertical power transistor, the CMOS device comprising one or more PMOS cells and one or more NMOS cells, wherein each PMOS cell and each NMOS cell of the CMOS device comprises a source region at the first main surface, a drift region, a gate trench extending into the semiconductor substrate from the first main surface, a gate electrode in the gate trench and comprising doped polycrystalline silicon, and a dielectric material separating the gate electrode from the semiconductor substrate; and forming a metal silicide region that adjoins the doped polycrystalline silicon in an upper central part of each of the gate electrodes of the CMOS device.
Example 19. The method of example 18, further comprising: before forming the metal silicide region in the upper central part of each gate electrode of the vertical power transistor and before forming the metal silicide region in the upper central part of each gate electrode of the CMOS device, concurrently doping the gate electrode of each power transistor cell and the gate electrode of each NMOS cell with a dopant species of a first doping type while each PMOS cell is masked, and doping the gate electrode of each PMOS cell with a dopant species of the first doping type or a dopant species of a second doping type opposite the first doping type while each power transistor cell and each NMOS cell are masked.
Example 20. The method of example 18 or 19, further comprising: after doping the polycrystalline or amorphous silicon in each gate electrode of the CMOS device and doping the polycrystalline or amorphous silicon in each gate electrode of the vertical power transistor, etching the semiconductor substrate to form a recess between adjacent gate trenches of a same cell type of the CMOS device; forming a dielectric mesa in the recess between the adjacent gate trenches of the same cell type of the CMOS device; and after forming the metal silicide region, forming a contact that extends through the dielectric mesa to or into the semiconductor substrate.
Example 21. The method of example 20, wherein forming the dielectric mesa in the recess comprises: filling the recess and covering the first main surface of the semiconductor substrate with a dielectric material; and planarizing an upper surface of the dielectric material that faces away from the semiconductor substrate.
Example 22. The method of example 21, wherein forming the metal silicide region in the upper central part of each gate electrode of the vertical power transistor and forming the metal silicide region in the upper central part of each gate electrode of the CMOS device comprises: covering the planarized upper surface of the dielectric material with a photoresist having openings that are vertically aligned with the gate electrodes of the vertical power transistor and the gate electrodes of the CMOS device; forming openings in the dielectric material that are vertically aligned with the openings of the photoresist; after filling the recess and covering the first main surface of the semiconductor substrate with the dielectric material, removing the photoresist; recessing the gate electrodes of the vertical power transistor and the gate electrodes of the CMOS device through the openings of the photoresist and the openings of the dielectric material; after removing the photoresist, depositing cobalt over the first main surface of the semiconductor substrate such that the cobalt comes into contact with the recessed gate electrodes of the vertical power transistor and the recessed gate electrodes of the CMOS device; and annealing the cobalt.
Example 23. The method of any of examples 18 through 22, wherein forming the metal silicide region in the upper central part of each gate electrode of the vertical power transistor and forming the metal silicide region in the upper central part of each gate electrode of the CMOS device comprises: recessing the gate electrodes of the vertical power transistor and the gate electrodes of the CMOS device; depositing cobalt over the first main surface of the semiconductor substrate such that the cobalt comes into contact with the recessed part of each gate electrode of the vertical power transistor and the recessed part of each gate electrode of the CMOS device; depositing titanium on the cobalt; performing a first anneal process that yields CoSi in contact with the recessed part of each gate electrode of the vertical power transistor and the recessed part of each gate electrode of the CMOS device, and a TiN layer on the CoSi; removing the TIN layer and unreacted Co; and performing a second anneal process at a higher temperature than the first anneal process but less than 1000° C.

Terms such as “first”, “second”, and the like, are used to describe various elements, regions, sections, etc. and are also not intended to be limiting. Like terms refer to like elements throughout the description.

As used herein, the terms “having”, “containing”, “including”, “comprising” and the like are open ended terms that indicate the presence of stated elements or features, but do not preclude additional elements or features. The articles “a”, “an” and “the” are intended to include the plural as well as the singular, unless the context clearly indicates otherwise.

It is to be understood that the features of the various embodiments described herein may be combined with each other, unless specifically noted otherwise.

Although specific embodiments have been illustrated and described herein, it will be appreciated by those of ordinary skill in the art that a variety of alternate and/or equivalent implementations may be substituted for the specific embodiments shown and described without departing from the scope of the present invention. This application is intended to cover any adaptations or variations of the specific embodiments discussed herein. Therefore, it is intended that this invention be limited only by the claims and the equivalents thereof.

What is claimed is:

1. A semiconductor device, comprising:
a vertical power transistor comprising a plurality of power transistor cells,
wherein each of the power transistor cells comprises a source region at a first main surface of a semiconductor substrate, a drain region at a second main surface of the semiconductor substrate opposite the first main surface, a gate trench extending into the semiconductor substrate from the first main surface, a gate electrode in the gate trench and comprising doped polycrystalline silicon, and a dielectric material separating the gate electrode from the semiconductor substrate,
wherein an upper central part of each of the gate electrodes of the power transistor cells is occupied by a metal silicide region that adjoins the doped polycrystalline silicon.

2. The semiconductor device of claim 1, wherein the vertical power transistor is a n-channel device, and wherein the doped polycrystalline silicon is n-doped.

3. The semiconductor device of claim 1, wherein the vertical power transistor is a p-channel device, and wherein the doped polycrystalline silicon is p-doped or n-doped.

4. The semiconductor device of claim 1, wherein the metal silicide region is spaced inward from sidewalls and a bottom of each of the gate trenches of the power transistor cells.

5. The semiconductor device of claim 1, wherein an upper surface of the doped polycrystalline silicon has a recess that is laterally spaced inward from sidewalls of each of the gate trenches of the power transistor cells, and wherein the metal silicide region is formed along sidewalls and a bottom of the recess in each of the gate trenches of the power transistor cells.

6. The semiconductor device of claim 5, wherein for each of the gate electrodes, the recess is in a range of up to 25% of a thickness of the gate electrode.

7. The semiconductor device of claim 5, wherein for each of the gate electrodes, the recess is in a range of 10 nm to 100 nm below the first main surface of the semiconductor substrate.

8. The semiconductor device of claim 1, further comprising:
a CMOS (complementary metal-oxide-semiconductor) device monolithically integrated in the same semiconductor substrate as the vertical power transistor and comprising one or more PMOS cells and one or more NMOS cells,
wherein each PMOS cell and each NMOS cell of the CMOS device comprises a source region at the first main surface, a drift region, a gate trench extending into the semiconductor substrate from the first main surface, a gate electrode in the gate trench and comprising doped polycrystalline silicon, and a dielectric material separating the gate electrode from the semiconductor substrate,
wherein an upper central part of each of the gate electrodes of the CMOS device is occupied by a metal silicide region that adjoins the doped polycrystalline silicon.

9. The semiconductor device of claim 8, wherein adjacent gate trenches of a same cell type of the CMOS device are laterally separated from one another by a dielectric mesa, and wherein a contact extends through the dielectric mesa to or into the semiconductor substrate to provide a drain connection.

10. The semiconductor device of claim 8, wherein the vertical power transistor is a n-channel device, wherein the doped polycrystalline silicon in each of the gate trenches of the power transistor cells is n-doped, wherein the doped polycrystalline silicon in the gate trench of each NMOS cell of the CMOS device is n-doped, and wherein the doped polycrystalline silicon in the gate trench of each PMOS cell of the CMOS device is p-doped or n-doped.

11. The semiconductor device of claim 8, wherein the vertical power transistor is a p-channel device, wherein the doped polycrystalline silicon in each of the gate trenches of the power transistor cells is p-doped or n-doped, wherein the doped polycrystalline silicon in the gate trench of each NMOS cell of the CMOS device is n-doped, and wherein the doped polycrystalline silicon in the gate trench of each PMOS cell of the CMOS device is p-doped or n-doped.

12. The semiconductor device of claim 8, wherein an upper surface of the doped polycrystalline silicon has a recess that is laterally spaced inward from sidewalls of each of the gate trenches of both the vertical power transistor and the CMOS device, and wherein the metal silicide region is formed along sidewalls and a bottom of the recess in each of the gate trenches of both the vertical power transistor and the CMOS device.

13. The semiconductor device of claim 8, wherein the metal silicide region that occupies the upper central part of the gate electrode of neighboring NMOS and PMOS cells provides a connection across a pn-junction at a boundary of the neighboring NMOS and PMOS cells.

14. The semiconductor device of claim 1, wherein an upper surface of each of the gate electrodes is coplanar with the first main surface of the semiconductor substrate.

15. The semiconductor device of claim 1, wherein an upper surface of each of the gate electrodes is recessed below the first main surface of the semiconductor substrate.

16. The semiconductor device of claim 1, wherein an upper surface of each of the gate electrodes is completely covered only by oxide.

17. A method of producing a semiconductor device, the method comprising:
forming a vertical power transistor having a plurality of power transistor cells, wherein each of the power transistor cells comprises a source region at a first main surface of a semiconductor substrate, a drain region at a second main surface of the semiconductor substrate opposite the first main surface, a gate trench extending into the semiconductor substrate from the first main surface, a gate electrode in the gate trench and comprising doped polycrystalline silicon, and a dielectric material separating the gate electrode from the semiconductor substrate; and
forming a metal silicide region that adjoins the doped polycrystalline silicon in an upper part central of each of the gate electrodes of the power transistor cells.

18. The method of claim 17, further comprising:
monolithically integrating a CMOS (complementary metal-oxide-semiconductor) device in the same semiconductor substrate as the vertical power transistor, the CMOS device comprising one or more PMOS cells and one or more NMOS cells, wherein each PMOS cell and each NMOS cell of the CMOS device comprises a source region at the first main surface, a drift region, a gate trench extending into the semiconductor substrate from the first main surface, a gate electrode in the gate trench and comprising doped polycrystalline silicon, and a dielectric material separating the gate electrode from the semiconductor substrate; and
forming a metal silicide region that adjoins the doped polycrystalline silicon in an upper central part of each of the gate electrodes of the CMOS device.

19. The method of claim 18, further comprising:
before forming the metal silicide region in the upper central part of each gate electrode of the vertical power transistor and before forming the metal silicide region in the upper central part of each gate electrode of the CMOS device, concurrently doping the gate electrode of each power transistor cell and the gate electrode of each NMOS cell with a dopant species of a first doping type while each PMOS cell is masked, and doping the gate electrode of each PMOS cell with a dopant species of the first doping type or a dopant species of a second doping type opposite the first doping type while each power transistor cell and each NMOS cell are masked.

20. The method of claim 18, further comprising:
after doping the polycrystalline or amorphous silicon in each gate electrode of the CMOS device and doping the polycrystalline or amorphous silicon in each gate electrode of the vertical power transistor, etching the semiconductor substrate to form a recess between adjacent gate trenches of a same cell type of the CMOS device;
forming a dielectric mesa in the recess between the adjacent gate trenches of the same cell type of the CMOS device; and
after forming the metal silicide region, forming a contact that extends through the dielectric mesa to or into the semiconductor substrate.

21. The method of claim 20, wherein forming the dielectric mesa in the recess comprises:
filling the recess and covering the first main surface of the semiconductor substrate with a dielectric material; and
planarizing an upper surface of the dielectric material that faces away from the semiconductor substrate.

22. The method of claim 21, wherein forming the metal silicide region in the upper central part of each gate electrode of the vertical power transistor and forming the metal silicide region in the upper central part of each gate electrode of the CMOS device comprises:
covering the planarized upper surface of the dielectric material with a photoresist having openings that are vertically aligned with the gate electrodes of the vertical power transistor and the gate electrodes of the CMOS device;
forming openings in the dielectric material that are vertically aligned with the openings of the photoresist;
after filling the recess and covering the first main surface of the semiconductor substrate with the dielectric material, removing the photoresist;
recessing the gate electrodes of the vertical power transistor and the gate electrodes of the CMOS device through the openings of the photoresist and the openings of the dielectric material;
after removing the photoresist, depositing cobalt over the first main surface of the semiconductor substrate such that the cobalt comes into contact with the recessed gate electrodes of the vertical power transistor and the recessed gate electrodes of the CMOS device; and
annealing the cobalt.

23. The method of claim 18, wherein forming the metal silicide region in the upper central part of each gate electrode of the vertical power transistor and forming the metal silicide region in the upper central part of each gate electrode of the CMOS device comprises:
recessing the gate electrodes of the vertical power transistor and the gate electrodes of the CMOS device;
depositing cobalt over the first main surface of the semiconductor substrate such that the cobalt comes into contact with the recessed part of each gate electrode of the vertical power transistor and the recessed part of each gate electrode of the CMOS device;
depositing titanium on the cobalt;
performing a first anneal process that yields CoSi in contact with the recessed part of each gate electrode of the vertical power transistor and the recessed part of each gate electrode of the CMOS device, and a TiN layer on the CoSi;
removing the TiN layer and unreacted Co; and
performing a second anneal process at a higher temperature than the first anneal process but less than 1000° C.
